(19) United States
(12) Patent Application Publication
(10) Pub. No.: US 2026/0227454 A1
(43) Pub. Date: Aug. 6, 2026

(54) APPARATUS AND METHOD FOR DIAGNOSING BATTERY CELL DEGRADATION AND SWELLING

(71) Applicants: HYUNDAI MOTOR COMPANY, Seoul (KR); KIA CORPORATION, Seoul (KR)

(72) Inventors: Ki Young Lee, Hwaseong-si (KR); Jae Kyung Oh, Hwaseong-si (KR)

(73) Assignees: HYUNDAI MOTOR COMPANY, Seoul (KR); KIA CORPORATION, Seoul (KR)

(21) Appl. No.: 19/282,855

(22) Filed: Jul. 28, 2025

(30) Foreign Application Priority Data
Feb. 5, 2025 (KR) 10-2025-0014793

(51) Int. Cl. G01R 31/392; B60L 58/16; G01R 31/367; G01R 31/396; H02J 7/00

(52) U.S. Cl. CPC G01R 31/392; B60L 58/16; G01R 31/367; G01R 31/396; H02J 7/825

(57) ABSTRACT

A battery cell swelling and degradation diagnosing apparatus includes a memory configured to store battery cell-specific voltage values corresponding to charging or discharging, and a processor configured to diagnose swelling and degradation of the battery cell based on the battery cell-specific voltage values.

### CROSS-REFERENCE TO RELATED APPLICATION

This application claims the benefit of and priority to Korean Patent Application No. 10-2025-0014793, filed on Feb. 5, 2025, the entire contents of which are hereby incorporated herein by reference.

### TECHNICAL FIELD

The present disclosure relates to an apparatus and a method for diagnosing battery cell swelling and degradation.

### BACKGROUND

The statements in this section merely provide background information related to the present disclosure and may not constitute prior art.

In general, in a battery system (BSA) and battery module (BSM) structure, because the entire battery structure is tightly sealed, a diagnosis method that is based on sensing data of a battery management system (BMS) is used to diagnose the inside of the battery from the outside of the battery.

According to the above battery system, due to a surface pressure structure, it is difficult to maintain a surface pressure of the outermost battery cell of the battery module; in this case, the battery module is vulnerable to cell swelling.

If a swelling phenomenon occurs due to the degradation of the battery cell, a battery capacity may be reduced due to a sharp decrease in a voltage during discharging the corresponding cell.

Generally, if a state of charge (SOC) is determined by the vehicle in a state where the battery capacity is reduced, because the SOC is determined based on the minimum voltage cell, a driving distance of the vehicle decreases; in this case, the driver has no choice but to suffer inconvenience.

However, because logic and an algorithm for diagnosing the cell swelling are absent from current BMS logic, if the driver experiences the sharp decrease in the SOC or the decrease in the driving distance due to the cell swelling, the driver puts the vehicle in a service center to diagnose the battery swelling via battery pack decomposition. For this reason, the stability and convenience of the driver are reduced.

### SUMMARY

The present disclosure has been made to solve the above-mentioned problems occurring in the prior art while advantages achieved by the prior art are maintained intact.

An aspect of the present disclosure provides an apparatus and a method for diagnosing battery cell swelling and degradation, that are capable of predicting swelling and degradation phenomena of a battery cell by performing diagnosis logic based on a voltage difference of a maximum charging voltage cell and a minimum charging voltage cell and whether a minimum discharging voltage cell number is the same as a maximum charging voltage cell number.

The technical problems to be solved by the present disclosure are not limited to the aforementioned problems. Other technical problems not mentioned herein should be more clearly understood from the following description by those having ordinary skill in the art to which the present disclosure pertains.

According to an aspect of the present disclosure, a battery cell swelling and degradation diagnosing apparatus is provided. The battery cell swelling and degradation diagnosing apparatus includes a memory configured to store battery cell-specific voltage values corresponding to charging or discharging, and a processor configured to diagnose swelling and degradation of a battery cell of a battery based on the battery cell-specific voltage values. The processor may be configured to determine, based on determining that the battery is fully charged, whether a difference between a first voltage of a maximum charging voltage cell and a second voltage of a minimum charging voltage cell, from among battery cell-specific voltage values corresponding to the charging, is greater than or equal to a preset specific threshold voltage. The processor is also configured to store a maximum charging voltage cell number in the memory based on determining that the difference between the first voltage and the second voltage is greater than or equal to the preset specific threshold voltage. The processor is additionally configured to obtain, based on determining that the battery is being discharged, a minimum discharging voltage cell number from the battery cell-specific voltage values corresponding to the discharging. The processor is further configured to diagnose whether swelling or degradation is made at a minimum discharging voltage cell based on a preset diagnosis condition, based on determining that the obtained minimum discharging voltage cell number is the same as the maximum charging voltage cell number.

In an embodiment, the processor may be configured to determine that the battery is fully charged based on determining that a state of charge (SOC) of the battery is at least approximately 100 percent. The processor may be configured to may extract the first voltage of the maximum charging voltage cell and the second voltage of the minimum charging voltage cell based on the battery cell-specific voltage values. The processor may be configured to determine whether the difference between the first voltage and the second voltage is greater than or equal to the specific threshold voltage.

In an embodiment, the processor may be configured to determine a cell number assigned in advance to the maximum charging voltage cell based on determining that the difference between the first voltage of the maximum charging voltage cell and the second voltage of the minimum charging voltage cell is greater than or equal to the preset specific threshold voltage, and store the maximum charging voltage cell number in the memory.

In an embodiment, the processor may be configured to determine that the battery is being discharged based on determining that a vehicle in which the battery is included starts driving. The processor may be configured to obtain the battery cell-specific voltage values corresponding to the discharging. The processor may be configured to search the obtained battery cell-specific voltage values for a minimum discharging voltage cell with a minimum voltage. The processor may be configured to obtain the minimum discharging voltage cell number by checking a cell number assigned in advance to the minimum discharging voltage cell based on the minimum discharging voltage cell being found.

In an embodiment, the processor may be configured to determine whether the obtained minimum discharging voltage cell number is the same as the maximum charging voltage cell number stored in the memory based on the minimum discharging voltage cell number being found. The processor may be configured to diagnose whether the swelling or degradation is made at the minimum discharging voltage cell based on the preset diagnosis condition, based on determining that the minimum discharging voltage cell number is the same as the maximum charging voltage cell number.

In an embodiment, the processor may be configured to calculate a first voltage slope of the minimum discharging voltage cell and a second voltage slope of a maximum discharging voltage cell from the battery cell-specific voltage values corresponding to the discharging. The processor may be configured to diagnose a degradation level of the minimum discharging voltage cell based on a deviation between a first voltage of the minimum discharging voltage cell and a second voltage of the maximum discharging voltage cell based on determining that a difference between the first voltage slope and the second voltage slope is greater than or equal to a preset value. The processor may be configured to diagnose the minimum discharging voltage cell as a swelling cell based on determining that the minimum discharging voltage cell satisfies a preset first diagnosis condition. The processor may be configured to diagnose the minimum discharging voltage cell as a degraded cell based on determining that the minimum discharging voltage cell satisfies a preset second diagnosis condition.

In an embodiment, the processor may be configured to diagnose the degradation level of the minimum discharging voltage cell as a first level based on determining that the deviation between the first voltage and the second voltage is within a first setting range. The processor may may be configured to diagnose the degradation level of the minimum discharging voltage cell as a second level based on determining that the deviation between the first voltage and the second voltage is within a second setting range. The processor may be configured to diagnose the degradation level of the minimum discharging voltage cell as a third level based on determining that the deviation between the first voltage and the second voltage is greater than or equal to a specific setting range.

In an embodiment, the processor may be configured to diagnose the minimum discharging voltage cell as the swelling cell based on determining that the preset first diagnosis condition that the minimum discharging voltage cell is an outermost battery cell in the battery is satisfied.

In an embodiment, the processor may be configured to diagnose the minimum discharging voltage cell as the degraded cell based on determining that the preset second diagnosis condition that a cell resistance value of the minimum discharging voltage cell is within a specific resistance range is satisfied.

According to another aspect of the present disclosure, a cell swelling and degradation diagnosing method is provided. The cell swelling and degradation diagnosing method includes determining whether a battery is fully charged and determining, based on determining that the batter is fully charged, whether a difference between a first voltage of a maximum charging voltage cell and a second voltage of a minimum charging voltage cell, from among battery cell-specific voltage values corresponding to charging, is greater than or equal to a preset specific threshold voltage. The cell swelling and degradation diagnosing method also includes storing a maximum charging voltage cell number based on determining that the difference between the first voltage and the second voltage is greater than or equal to the preset specific threshold voltage. The cell swelling and degradation diagnosing method additionally includes determining whether the battery is being discharged and obtaining, based on determining that the battery is being discharged, a minimum discharging voltage cell number from battery cell-specific voltage values corresponding to discharging. The cell swelling and degradation diagnosing method further includes determining whether the obtained minimum discharging voltage cell number is the same as the maximum charging voltage cell number. The cell swelling and degradation diagnosing method additionally includes diagnosing whether swelling or degradation is made at a minimum discharging voltage cell based on a preset diagnosis condition, based on determining that the obtained minimum discharging voltage cell number is the same as the maximum charging voltage cell number.

### BRIEF DESCRIPTION OF THE DRAWINGS

The above and other objects, features, and advantages of the present disclosure should become more apparent from the following detailed description taken in conjunction with the accompanying drawings, in which:

FIG. 1 is a diagram for describing a vehicle including a battery cell swelling and degradation diagnosing apparatus according to an embodiment of the present disclosure;

FIG. 2 is a block diagram illustrating a configuration of a battery cell swelling and degradation diagnosing apparatus according to an embodiment of the present disclosure;

FIG. 3 is a graph illustrating changes of voltage slopes of a normal battery cell and an abnormal battery cell according to an embodiment of the present disclosure;

FIG. 4 is a graph illustrating changes of vehicle-specific voltage slopes according to an embodiment of the present disclosure;

FIG. 5 is a diagram comparing DC internal resistances of a normal battery cell and a degraded battery cell according to an embodiment of the present disclosure;

FIG. 6 is a flowchart for describing a vehicle battery cell swelling and degradation diagnosing method according to an embodiment of the present disclosure; and

FIG. 7 illustrates a computing system of a vehicle according to an embodiment of the present disclosure.

The drawings described herein are for illustration purposes only and are not intended to limit the scope of the present disclosure in any way.

### DETAILED DESCRIPTION

Below, some embodiments of the present disclosure are described in detail with reference to the accompanying drawings. In adding the reference numerals to the components of each drawing, it should be noted that the identical components are designated by the identical numerals even if the components are displayed on different drawings. Further, in describing the embodiment of the present disclosure, where it was determined that a detailed description of well-known features or functions would unnecessarily obscure the gist of the present disclosure, the detailed description thereof has been has been omitted.

In describing the components of the embodiment according to the present disclosure, terms such as first, second, “A”, “B”, (a), (b), and the like may be used. These terms are merely intended to distinguish one component from another component, and the terms do not limit the nature, sequence, or order of the corresponding components. Furthermore, unless otherwise defined, all terms including technical and scientific terms used herein have the same meaning as being generally understood by those having ordinary skill in the art to which the present disclosure pertains. Such terms as those defined in a generally used dictionary should be interpreted as having meanings equal to the contextual meanings in the relevant field of art, and should not be interpreted as having ideal or excessively formal meanings unless clearly defined as having such in the present disclosure.

Unless otherwise specified, all numbers, values, and/or representations that express the amounts or values should be taken as approximations including various uncertainties affecting measurement that inherently occur in obtaining these values, among others, and thus should be understood to be modified by the term “about” or “at least approximately” in all cases. Furthermore, when a numerical range is disclosed in this specification, the range is continuous, and includes all values from the minimum value of said range to the maximum value thereof, unless otherwise indicated.

In the present disclosure, when a component, controller, device, element, apparatus, unit or the like of the present disclosure is described as having a purpose or performing an operation, function, or the like, the component, controller, device, element, apparatus, unit or the like should be considered herein as being “configured to” meet that purpose or to perform that operation or function. Each component, controller, device, element, apparatus, unit, server, and the like may separately embody or be included with a processor and a memory, such as a non-transitory computer readable media, as part of the apparatus.

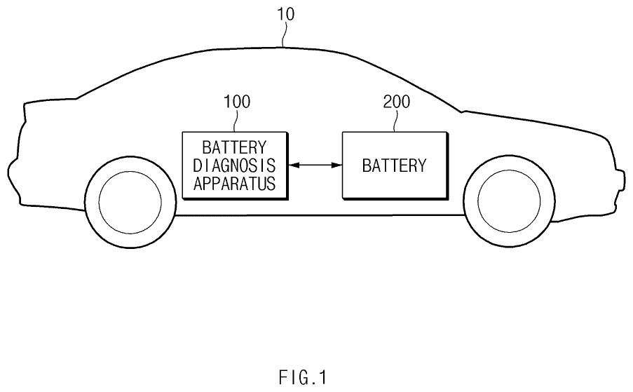

Hereinafter, embodiments of the present disclosure are described in detail with reference to FIGS. 1-7.

FIG. 1 is a diagram for describing a vehicle including a battery cell swelling and degradation diagnosing apparatus according to an embodiment of the present disclosure.

As illustrated in FIG. 1, a battery diagnosis apparatus 100 is a battery cell swelling and degradation diagnosing apparatus according to an embodiment of the present disclosure. The battery diagnosis apparatus 100 may be configured to diagnose swelling and degradation of a battery cell based on battery cell-specific voltage values obtained from a battery 200 of a vehicle 10.

In various embodiments, the battery diagnosis apparatus 100 may be internally mounted within the vehicle 10 or may be disposed on the outside of the vehicle 10 so as to be removable.

The battery diagnosis apparatus 100 may determine (e.g., may check) whether a difference between a first voltage of a maximum charging voltage cell and a second voltage of a minimum charging voltage cell is greater than or equal to a specific threshold voltage, from battery cell-specific voltage values corresponding to the charging if the battery 200 of the vehicle 10 is fully charged. The battery diagnosis apparatus 100 may store (e.g., may record) a maximum charging voltage cell number in a memory if the difference between the first voltage and the second voltage is greater than or equal to the specific threshold voltage. The battery diagnosis apparatus 100 may also obtain a minimum discharging voltage cell number from battery cell-specific voltage values corresponding to the discharging if the battery 200 of the vehicle 10 is being discharged. The battery diagnosis apparatus 100 may diagnose whether swelling or degradation is made at a minimum discharging voltage cell based on a preset diagnosis condition if the obtained minimum discharging voltage cell number is the same as the maximum charging voltage cell number.

In an embodiment, when the difference is greater than or equal to the specific threshold voltage, the battery diagnosis apparatus 100 may determine that the battery 200 of the vehicle 10 is fully charged if a state of charge (SOC) is at least approximately 100 percent, may extract the first voltage of the maximum charging voltage cell and the second voltage of the minimum charging voltage cell based on the battery cell-specific voltage values, and may check whether the difference between the first voltage and the second voltage thus extracted is greater than or equal to the specific threshold voltage.

Also, when the battery diagnosis apparatus 100 stores the maximum charging voltage cell number in the memory, the battery diagnosis apparatus 100 may check a cell number assigned in advance to a maximum charging cell if the difference between the first voltage of the maximum charging voltage cell and the second voltage of the minimum charging voltage cell is greater than or equal to the preset specific threshold voltage and may store the maximum charging voltage cell number in the memory.

In addition, when the battery diagnosis apparatus 100 obtains the minimum discharging voltage cell number, the battery diagnosis apparatus 100 may recognize that the battery 200 of the vehicle 10 is being discharged when the vehicle 10 starts driving, may obtain the battery cell-specific voltage values corresponding to the discharging, may search the obtained battery cell-specific voltage values for a minimum discharging voltage cell with a minimum voltage, and may obtain the minimum discharging voltage cell number by checking a cell number assigned in advance to the minimum discharging voltage cell if the minimum discharging voltage cell is found.

Furthermore, when the battery diagnosis apparatus 100 diagnoses whether the swelling or degradation is made, the battery diagnosis apparatus 100 may check whether the obtained minimum discharging voltage cell number is the same as the maximum charging voltage cell number stored in the memory if the minimum discharging voltage cell number is found, and may diagnose whether the swelling or degradation is made at the minimum discharging voltage cell based on the preset diagnosis condition if the minimum discharging voltage cell number is the same as the maximum charging voltage cell number.

In an embodiment, when the battery diagnosis apparatus 100 diagnoses whether the swelling or degradation is made, the battery diagnosis apparatus 100 may calculate a first voltage slope of the minimum discharging voltage cell and a second voltage slope of the maximum discharging voltage cell from the battery cell-specific voltage values corresponding to the discharging, may diagnose a degradation level of the minimum discharging voltage cell based on a deviation between a first voltage of the minimum discharging voltage cell and a second voltage of the maximum discharging voltage cell if a difference between the first voltage slope and the second voltage slope is greater than or equal to a preset value, may diagnose the minimum discharging voltage cell as a swelling cell if the minimum discharging voltage cell satisfies a preset first diagnosis condition, and may diagnose the minimum discharging voltage cell as a degraded cell if the minimum discharging voltage cell satisfies a preset second diagnosis condition.

As an example, when the battery diagnosis apparatus 100 diagnoses the degradation level, the battery diagnosis apparatus 100 may diagnose the degradation level of the minimum discharging voltage cell as a first level if the deviation between the first voltage and the second voltage is within a first setting range, may diagnose the degradation level of the minimum discharging voltage cell as a second level if the deviation between the first voltage and the second voltage is within a second setting range, and may diagnose the degradation level of the minimum discharging voltage cell as a third level if the deviation between the first voltage and the second voltage is greater than or equal to a specific setting value.

Also, when the battery diagnosis apparatus 100 diagnoses the minimum discharging voltage cell as the swelling cell, the battery diagnosis apparatus 100 may diagnose the minimum discharging voltage cell as the swelling cell if the first diagnosis condition that the minimum discharging voltage cell is the outermost battery cell in the battery 200 of the vehicle 10 is satisfied.

In addition, when the battery diagnosis apparatus 100 diagnoses the minimum discharging voltage cell as the degraded cell, the battery diagnosis apparatus 100 may diagnose the minimum discharging voltage cell as the degraded cell if the second diagnosis condition that a cell resistance value of the minimum discharging voltage cell is within a specific resistance range is satisfied.

Accordingly, embodiments of the present disclosure may predict the swelling and degradation phenomena of the battery cell in advance by performing diagnosis logic based on a voltage difference of the maximum charging voltage cell and the minimum charging voltage cell and whether the minimum discharging voltage cell number is the same as the maximum charging voltage cell number and may in advance block the field issue of failing to predict the swelling and degradation of the battery cell.

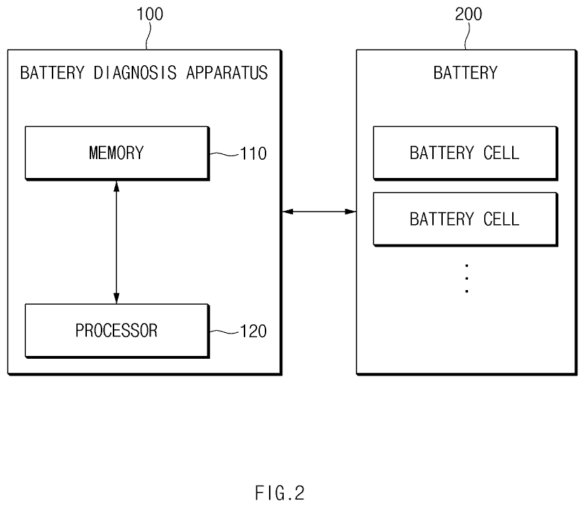

FIG. 2 is a block diagram illustrating a configuration of a battery cell swelling and degradation diagnosing apparatus according to an embodiment of the present disclosure.

As illustrated in FIG. 2, the battery diagnosis apparatus 100 may include a memory 110 configured to store battery cell-specific voltage values corresponding to the charging or discharging, and a processor 120 configured to diagnose swelling and degradation of each battery cell of the battery 200 based on the battery cell-specific voltage values.

In an embodiment, the processor 120 may determine (e.g., may check) whether a difference between a first voltage of a maximum charging voltage cell and a second voltage of a minimum charging voltage cell is greater than or equal to the specific threshold voltage, from the battery cell-specific voltage values corresponding to the charging if the battery 200 of the vehicle is fully charged. The processor 120 may store a maximum charging voltage cell number in the memory 110 if the difference between the first voltage and the second voltage is greater than or equal to the specific threshold voltage. The processor 120 may may obtain a minimum discharging voltage cell number from the battery cell-specific voltage values corresponding to the discharging if the battery 200 of the vehicle is being discharged, and may diagnose whether swelling or degradation is made at a minimum discharging voltage cell based on a preset diagnosis condition if the obtained minimum discharging voltage cell number is the same as the maximum charging voltage cell number.

When the difference is greater than or equal to the specific threshold voltage, the processor 120 may determine that the battery 200 of the vehicle is fully charged if the SOC is at least approximately 100 percent, may extract the first voltage of the maximum charging voltage cell and the second voltage of the minimum charging voltage cell based on the battery cell-specific voltage values, and may check whether the difference between the first voltage and the second voltage thus extracted is greater than or equal to the specific threshold voltage.

As an example, when the difference is greater than or equal to the specific threshold voltage, the processor 120 may check whether the difference between the first voltage of the maximum charging voltage cell and the second voltage of the minimum charging voltage cell is greater than or equal to about 100 mV being the preset specific threshold voltage.

In an embodiment, the reason that the specific threshold voltage is set to about 100 mV or more is as follows. First, in the case of the CAN data or the VCRM data, because a voltage error of about 20 mV is capable of occurring in the quality of data, the specific threshold voltage is set to about 100 mV or more such that a minimum difference is caused in a situation where the quality is minimum. Secondly, because the resistance of the degraded cell is large, the specific threshold voltage is set to about 100 mV or more such that a voltage difference due to the increase in resistance is increased.

In an embodiment, when the processor 120 stores the maximum charging voltage cell number in the memory 110, the processor 120 may check a cell number assigned in advance to a maximum charging cell if the difference between the first voltage of the maximum charging voltage cell and the second voltage of the minimum charging voltage cell is greater than or equal to the preset specific threshold voltage and may store the maximum charging voltage cell number in the memory 110.

In addition, when the processor 120 obtains the minimum discharging voltage cell number, the processor 120 may recognize that the battery 200 of the vehicle is being discharged if the vehicle starts driving, may obtain the battery cell-specific voltage values corresponding to the discharging, may search the obtained battery cell-specific voltage values for a minimum discharging voltage cell with a minimum voltage, and may obtain a minimum discharging voltage cell number by checking a cell number assigned in advance to the minimum discharging voltage cell if the minimum discharging voltage cell is found.

Furthermore, when the processor 120 diagnoses whether the swelling or degradation is made, the processor 120 may check whether the obtained minimum discharging voltage cell number is the same as the maximum charging voltage cell number stored in the memory 110 if the minimum discharging voltage cell number is found, and may diagnose whether the swelling or degradation is made at the minimum discharging voltage cell based on the preset diagnosis condition if the minimum discharging voltage cell number is the same as the maximum charging voltage cell number.

In an embodiment, when the processor 120 diagnoses whether the swelling or degradation is made, the processor 120 may calculate a first voltage slope of the minimum discharging voltage cell and a second voltage slope of the maximum discharging voltage cell from the battery cell-specific voltage values corresponding to the discharging, may diagnose a degradation level of the minimum discharging voltage cell based on a deviation between a first voltage of the minimum discharging voltage cell and a second voltage of the maximum discharging voltage cell if a difference between the first voltage slope and the second voltage slope is greater than or equal to the preset value, may diagnose the minimum discharging voltage cell as a swelling cell if the minimum discharging voltage cell satisfies the preset first diagnosis condition, and may diagnose the minimum discharging voltage cell as a degraded cell if the minimum discharging voltage cell satisfies the preset second diagnosis condition.

When the processor 120 calculates the first voltage slope and the second voltage slope, the processor 120 may calculate the first voltage slope and the second voltage slope in proportion to an SOC decrease amount of the battery 200.

As an example, When the processor 120 calculates the first voltage slope and the second voltage slope, based on determination that the SOC decrease amount of the battery 200 is changed as much as about 20% or more, the processor 120 may calculate the first voltage slope and the second voltage slope in proportion to the SOC decrease amount of the battery 200.

When the processor 120 diagnoses the degradation level, the processor 120 may calculate a deviation between the first voltage of the minimum discharging voltage cell and the second voltage of the maximum discharging voltage cell based on determination that the SOC of the battery 200 is a specific value or less and may diagnose the degradation level of the minimum discharging voltage cell based on the deviation between the first voltage and the second voltage thus calculated.

As an example, if the SOC of the battery 200 is about 50% or less, the processor 120 may calculate the deviation between the first voltage and the second voltage.

Further, when the processor 120 diagnoses the degradation level, the processor 120 may diagnose the degradation level of the minimum discharging voltage cell as a first level if the deviation between the first voltage and the second voltage is within the first setting range, may diagnose the degradation level of the minimum discharging voltage cell as a second level if the deviation between the first voltage and the second voltage is within the second setting range, and may diagnose the degradation level of the minimum discharging voltage cell as a third level if the deviation between the first voltage and the second voltage is greater than or equal to the specific setting value.

As an example, the processor 120 may diagnose the degradation level of the minimum discharging voltage cell as a warning level if the deviation between the first voltage and the second voltage is within a range from about 0.6 V or more and less than about 0.8 V, may diagnose the degradation level of the minimum discharging voltage cell as a degradation-expected level if the deviation between the first voltage and the second voltage is within a range from about 0.8 V or more and less than about 1.0 V, and may diagnose the degradation level of the minimum discharging voltage cell as a hazardous level if the deviation between the first voltage and the second voltage is greater than or equal to about 1.0 V.

In an embodiment, if the degradation level of the minimum discharging voltage cell is the warning level, the processor 120 may generate a warning notification associated with battery degradation and may perform any one of a first manner of displaying the warning notification on a display screen and a second manner of providing the warning notification to a preset user device.

In some cases, if the degradation level of the minimum discharging voltage cell is the warning level, the processor 120 may internally track the vehicle to check a battery state of the vehicle.

Also, if the degradation level of the minimum discharging voltage cell is the degradation-expected level, the processor 120 may generate a guidance notification for guiding the visit to a car service center and may perform any one of the first manner of displaying the guidance notification on a display screen and the second manner of providing the guidance notification to the preset user device.

Also, if the degradation level of the minimum discharging voltage cell is the hazardous level, the processor 120 may generate a replacement notification for notifying battery replacement and may perform any one of a first manner of displaying the replacement notification on the display screen and a second manner of providing the replacement notification to the preset user device.

Then, when the processor 120 diagnoses the minimum discharging voltage cell as the swelling cell, the processor 120 may diagnose the minimum discharging voltage cell as the swelling cell if the first diagnosis condition that the minimum discharging voltage cell is the outermost battery cell in the battery 200 of the vehicle is satisfied.

As an example, when the processor 120 diagnoses the minimum discharging voltage cell as the swelling cell, the processor 120 may check a cell number of the minimum discharging voltage cell and may determine that the first diagnosis condition that the minimum discharging voltage cell is the outermost battery cell in the battery 200 of the vehicle is satisfied, if the checked cell number is the same as a cell number of the outermost battery cell in the battery 200 of the vehicle.

When the processor 120 diagnoses the minimum discharging voltage cell as the degraded cell, the processor 120 may diagnose the minimum discharging voltage cell as the degraded cell if the second diagnosis condition that a cell resistance value of the minimum discharging voltage cell is within the specific resistance range is satisfied.

As an example, when the processor 120 diagnoses the minimum discharging voltage cell as the degraded cell, the processor 120 may measure a cell resistance value of the minimum discharging voltage cell and may determine that the second diagnosis condition is satisfied if the measured cell resistance value is about 2 milliohms (mohm) to about 2.5 mohm.

According to the above description, embodiments of the present disclosure may predict the swelling and degradation phenomena of the battery cell in advance by performing diagnosis logic based on a voltage difference of the maximum charging voltage cell and the minimum charging voltage cell and whether the minimum discharging voltage cell number is the same as the maximum charging voltage cell number and may in advance block the field issue of failing to predict the swelling and degradation of the battery cell.

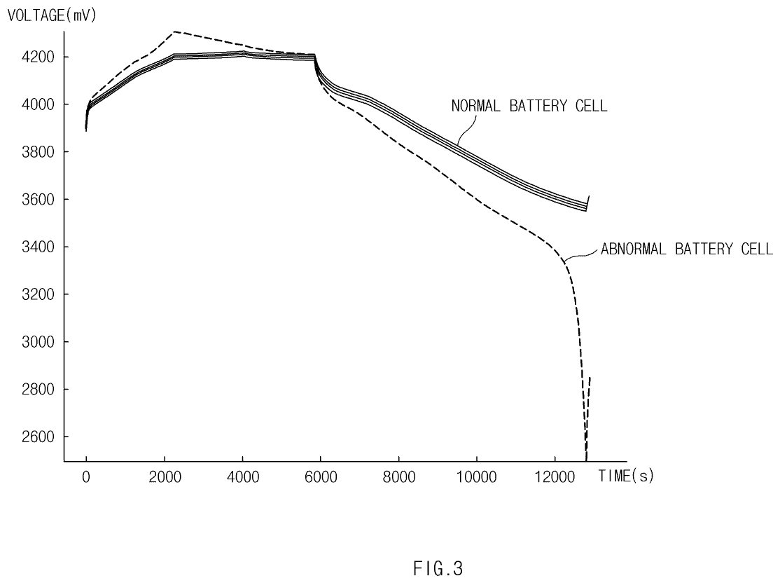

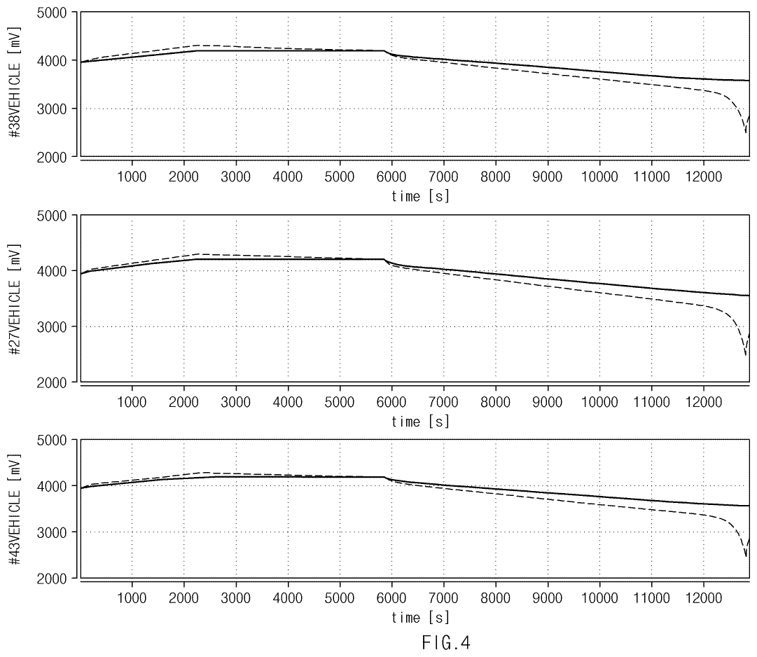

FIG. 3 is a graph illustrating changes of voltage slopes of a normal battery cell and an abnormal battery cell according to an embodiment of the present disclosure. FIG. 4 is a graph illustrating changes of vehicle-specific voltage slopes according to an embodiment of the present disclosure.

As illustrated in FIG. 3, as a battery cell is degraded, a swelling phenomenon may be caused. In this case, a voltage may sharply decrease during the discharging. This may mean that a phenomenon that a battery capacity is reduced occurs.

Because the determination of the SOC in the vehicle is made based on a minimum voltage cell in a situation where the phenomenon that a battery capacity is reduced occurs, a driving distance of the vehicle may decrease. For this reason, the driver has no choice but to suffer inconvenience.

It may be understood from FIG. 3 that a voltage deviation of a normal battery cell and an abnormal battery cell gradually increases due to the sharp decrease in the voltage of the abnormal battery cell while the battery is being discharged.

In an embodiment, the abnormal battery cell that appears while the battery is being discharged may be a battery cell which has a maximum voltage while the battery is being charged.

As illustrated in FIG. 4, changes in voltage slopes of vehicle-specific battery cells may be similar to each other if the battery cell is degraded.

In other words, as may be understood from the voltage slopes of the vehicle-specific battery cells illustrated in FIG. 4, a phenomenon that a voltage deviation of the normal battery cell and the abnormal battery cell gradually increases may appear in all the vehicles.

Accordingly, embodiments of the present disclosure may calculate a deviation between a first voltage of a minimum discharging voltage cell and a second voltage of a maximum discharging voltage cell and may diagnose a degradation level of the minimum discharging voltage cell based on the deviation between the first voltage and the second voltage thus calculated.

Embodiments of the present disclosure may diagnose the degradation level of the minimum discharging voltage cell as a first level if the deviation between the first voltage and the second voltage is within the first setting range, may diagnose the degradation level of the minimum discharging voltage cell as a second level if the deviation between the first voltage and the second voltage is within the second setting range, and may diagnose the degradation level of the minimum discharging voltage cell as a third level if the deviation between the first voltage and the second voltage is greater than or equal to the specific setting value.

As an example, embodiments of the present disclosure may diagnose the degradation level of the minimum discharging voltage cell as a warning level if the deviation between the first voltage and the second voltage is within a range from about 0.6 V or more and less than about 0.8 V, may diagnose the degradation level of the minimum discharging voltage cell as a degradation-expected level if the deviation between the first voltage and the second voltage is within a range from about 0.8 V or more and less than about 1.0 V, and may diagnose the degradation level of the minimum discharging voltage cell as a hazardous level if the deviation between the first voltage and the second voltage is greater than or equal to about 1.0 V.

Herein, if the degradation level of the minimum discharging voltage cell is the warning level, embodiments of the present disclosure may generate a warning notification associated with battery degradation and may perform any one of the first manner of displaying the warning notification on a display screen and the second manner of providing the warning notification to a preset user device.

In some cases, if the degradation level of the minimum discharging voltage cell is the warning level, embodiments of the present disclosure may internally track the vehicle to check a battery state of the vehicle.

Also, if the degradation level of the minimum discharging voltage cell is the degradation-expected level, embodiments of the present disclosure may generate a guidance notification for guiding the visit to a car service center and may perform any one of the first manner of displaying the guidance notification on a display screen and the second manner of providing the guidance notification to the preset user device.

Also, if the degradation level of the minimum discharging voltage cell is the hazardous level, embodiments of the present disclosure may generate a replacement notification for notifying battery replacement and may perform any one of the first manner of displaying the replacement notification on the display screen and the second manner of providing the replacement notification to the preset user device.

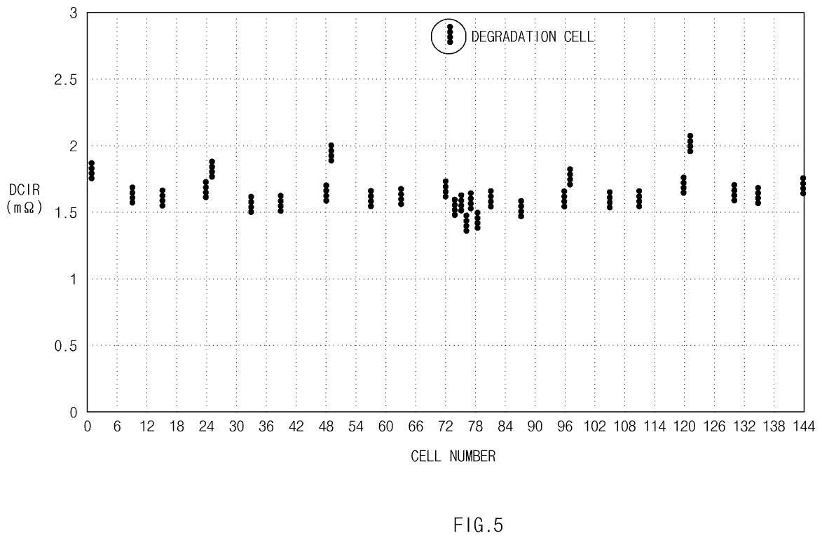

FIG. 5 is a diagram comparing DC internal resistances of a normal battery cell and a degraded battery cell according to an embodiment of the present disclosure.

As illustrated in FIG. 5, it may be understood from the present disclosure that if a DC internal resistance (DCIR) is measured for each battery cell, the DC internal resistance of a degraded battery cell appears to be higher than the DC internal resistance of a normal battery cell.

For example, it may be understood that the DC internal resistance of the normal battery cell appears to be less than about 1 mohm to about 2 mohm and that the DC internal resistance of the degraded battery cell appears to be less than about 2 mohm to about 2.5 mohm.

Accordingly, embodiments of the present disclosure may diagnose the minimum discharging voltage cell as a degraded cell if the second diagnosis condition that a cell resistance value of the minimum discharging voltage cell is within the specific resistance range is satisfied.

As an example, embodiments of the present disclosure may measure a cell resistance value of the minimum discharging voltage cell and may determine that the second diagnosis condition is satisfied if the measured cell resistance value is about 2 mohm to about 2.5 mohm.

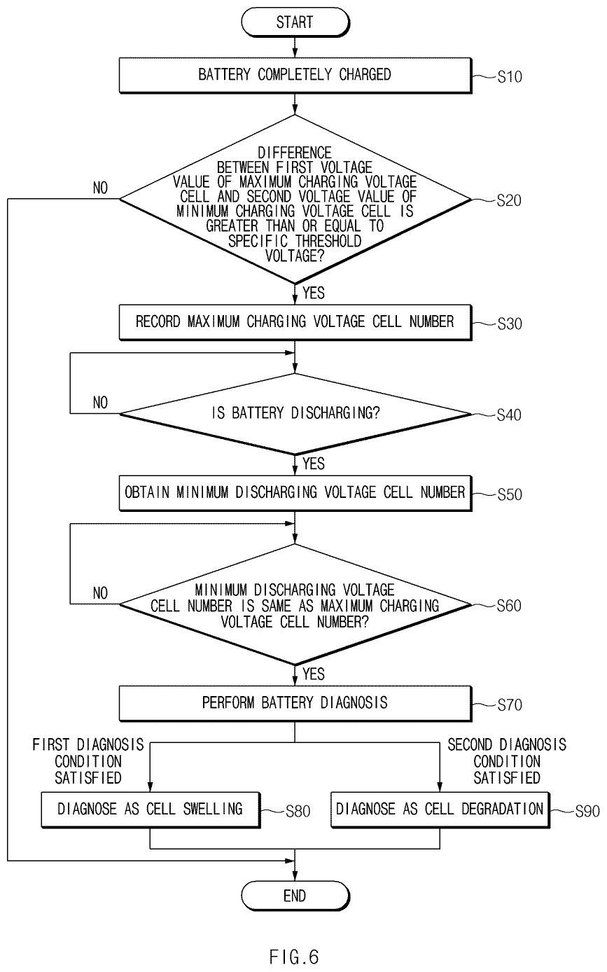

FIG. 6 is a flowchart for describing a vehicle battery cell swelling and degradation diagnosing method according to an embodiment of the present disclosure.

As illustrated in FIG. 6, in an operation S10, a processor (e.g., the processor 120) according to an embodiment of the present disclosure determine (e.g., may check) whether a battery of a vehicle is fully charged.

In an operation S20, the processor may determine (e.g., may check) whether a difference between a first voltage of a maximum charging voltage cell and a second voltage of a minimum charging voltage cell is greater than or equal to the specific threshold voltage if a battery of a vehicle is fully charged.

In an embodiment, the processor may determine that the battery of the vehicle is fully charged if the SOC of the battery is at least approximately 100 percent, may extract the first voltage of the maximum charging voltage cell and the second voltage of the minimum charging voltage cell based on battery cell-specific voltage values, and may check whether the difference between the first voltage and the second voltage thus extracted is greater than or equal to the specific threshold voltage.

In an operation S30, the processor may store (e.g., may record) a maximum charging voltage cell number if the difference between the first voltage and the second voltage is greater than or equal to the specific threshold voltage.

In an embodiment, the processor may check a cell number assigned in advance to a maximum charging cell if the difference between the first voltage of the maximum charging voltage cell and the second voltage of the minimum charging voltage cell is greater than or equal to the preset specific threshold voltage and may store (e.g., may record) the maximum charging voltage cell number in a memory.

In an operation S40, the processor may determine (e.g., may check) whether the battery of the vehicle is being discharged.

The processor may obtain the minimum discharging voltage cell number from battery cell-specific voltage values corresponding to the discharging if the battery of the vehicle is being discharged.

In an embodiment, the processor may recognize that the battery of the vehicle is being discharged if the vehicle starts driving, may obtain the battery cell-specific voltage values corresponding to the discharging, may search the obtained battery cell-specific voltage values for a minimum discharging voltage cell with a minimum voltage, and may obtain the minimum discharging voltage cell number by checking a cell number assigned in advance to the minimum discharging voltage cell if the minimum discharging voltage cell is found.

In an operation S60, the processor may check whether the obtained minimum discharging voltage cell number is the same as the maximum charging voltage cell number.

In an embodiment, the processor may determine (e.g., may check) whether the obtained minimum discharging voltage cell number is the same as the maximum charging voltage cell number stored or recorded in the memory if the minimum discharging voltage cell number is obtained.

In an operation S70, the processor may diagnose whether swelling or degradation is made at the minimum discharging voltage cell based on the preset diagnosis condition if the obtained minimum discharging voltage cell number is the same as the maximum charging voltage cell number.

In an embodiment, the processor may calculate a first voltage slope of the minimum discharging voltage cell and a second voltage slope of the maximum discharging voltage cell from the battery cell-specific voltage values corresponding to the discharging and may diagnose a degradation level of the minimum discharging voltage cell based on a deviation between a first voltage of the minimum discharging voltage cell and a second voltage of the maximum discharging voltage cell if a difference between the first voltage slope and the second voltage slope is greater than or equal to the preset setting value.

In an embodiment, the processor may diagnose the degradation level of the minimum discharging voltage cell as a first level if the deviation between the first voltage and the second voltage is within the first setting range, may diagnose the degradation level of the minimum discharging voltage cell as a second level if the deviation between the first voltage and the second voltage is within the second setting range, and may diagnose the degradation level of the minimum discharging voltage cell as a third level if the deviation between the first voltage and the second voltage is greater than or equal to the specific setting value.

In an operation S80, the processor may diagnose the minimum discharging voltage cell as a swelling cell if the first diagnosis condition that the minimum discharging voltage cell is the outermost battery cell in the battery of the vehicle is satisfied.

In an operation S90, the present disclosure may diagnose the minimum discharging voltage cell as a degraded cell if the second diagnosis condition that a cell resistance value of the minimum discharging voltage cell is within the specific resistance range is satisfied.

According to the above description, embodiments of the present disclosure may predict the swelling and degradation phenomena of the battery cell in advance by performing diagnosis logic based on a voltage difference of the maximum charging voltage cell and the minimum charging voltage cell and whether the minimum discharging voltage cell number is the same as the maximum charging voltage cell number and may in advance block the field issue of failing to predict the swelling and degradation of the battery cell.

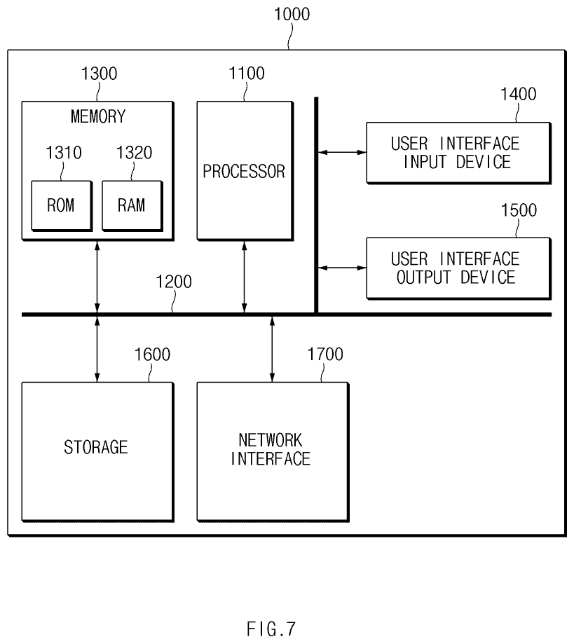

FIG. 7 illustrates a computing system of a vehicle according to an embodiment of the present disclosure.

Referring to FIG. 7, a computing system 1000 may include at least one processor 1100, a memory 1300, a user interface input device 1400, a user interface output device 1500, storage 1600, and a network interface 1700, which are connected via a bus 1200.

The processor 1100 may be a central processing unit (CPU) or a semiconductor device which processes instructions stored in the memory 1300 and/or the storage 1600. The memory 1300 and the storage 1600 may include various types of volatile or non-volatile storage media. For example, the memory 1300 may include a read only memory (ROM) 1310 and a random access memory (RAM) 1320.

Accordingly, the operations of the method or algorithm described in connection with the embodiments disclosed in the specification may be directly implemented with a hardware module, a software module, or a combination of the hardware module and the software module, which is executed by the processor 1100. The software module may reside in a storage medium (i.e., the memory 1300 and/or the storage 1600) such as a RAM, a flash memory, a ROM, an EPROM, an EEPROM, a register, a hard disk, a removable disk, and a CD-ROM.

The example storage medium may be coupled to the processor 1100. The processor 1100 may read information from the storage medium and may write information in the storage medium. As another example, the storage medium may be integrated with the processor 1100. The processor 1100 and the storage medium may reside in an application specific integrated circuit (ASIC). The ASIC may reside within a user terminal. As another example, the processor 1100 and the storage medium may reside in the user terminal as separate components.

Embodiments of the present disclosure may predict swelling and degradation phenomena of a battery cell in advance by performing diagnosis logic based on a voltage difference of a maximum charging voltage cell and a minimum charging voltage cell and whether a minimum discharging voltage cell number is the same as a maximum charging voltage cell number and may in advance block a field issue of failing to predict the swelling and degradation of the battery cell.

Hereinabove, although the present disclosure has been described with reference to example embodiments and the accompanying drawings, the present disclosure is not limited thereto, but may be variously modified and altered by those having ordinary skill in the art to which the present disclosure pertains without departing from the spirit and scope of the present disclosure claimed in the following claims.

What is claimed is:

1. A battery cell swelling and degradation diagnosing apparatus comprising:
a memory configured to store battery cell-specific voltage values corresponding to charging or discharging; and
a processor configured to diagnose swelling and degradation of a battery cell of a battery based on the battery cell-specific voltage values,
wherein the processor is configured to:
determine, based on determining that the battery is fully charged, whether a difference between a first voltage of a maximum charging voltage cell and a second voltage of a minimum charging voltage cell, from among battery cell-specific voltage values corresponding to the charging, is greater than or equal to a preset specific threshold voltage;
store a maximum charging voltage cell number in the memory based on determining that the difference between the first voltage and the second voltage is greater than or equal to the preset specific threshold voltage;
obtain, based on determining that the battery is being discharged, a minimum discharging voltage cell number from the battery cell-specific voltage values corresponding to the discharging; and
diagnose whether swelling or degradation is made at a minimum discharging voltage cell based on a preset diagnosis condition, based on determining that the obtained minimum discharging voltage cell number is the same as the maximum charging voltage cell number.

2. The battery cell swelling and degradation diagnosing apparatus of claim 1, wherein the processor is configured to:
determine that the battery is fully charged based on determining that a state of charge (SOC) of the battery is at least approximately 100 percent;
extract the first voltage of the maximum charging voltage cell and the second voltage of the minimum charging voltage cell based on the battery cell-specific voltage values; and
determine whether the difference between the first voltage and the second voltage is greater than or equal to the preset specific threshold voltage.

3. The battery cell swelling and degradation diagnosing apparatus of claim 1, wherein the processor is configured to:
determine a cell number assigned in advance to the maximum charging voltage cell based on determining that the difference between the first voltage of the maximum charging voltage cell and the second voltage of the minimum charging voltage cell is greater than or equal to the preset specific threshold voltage; and
store the maximum charging voltage cell number in the memory.

4. The battery cell swelling and degradation diagnosing apparatus of claim 1, wherein the processor is configured to:
recognize that the battery is being discharged based on determining that a vehicle in which the battery is included starts driving;
obtain the battery cell-specific voltage values corresponding to the discharging;
search the obtained battery cell-specific voltage values for a minimum discharging voltage cell with a minimum voltage; and
obtain the minimum discharging voltage cell number by checking a cell number assigned in advance to the minimum discharging voltage cell based on the minimum discharging voltage cell being found.

5. The battery cell swelling and degradation diagnosing apparatus of claim 1, wherein the processor is configured to:
determine whether the obtained minimum discharging voltage cell number is the same as the maximum charging voltage cell number stored in the memory based on the minimum discharging voltage cell number being found; and
diagnose whether the swelling or degradation is made at the minimum discharging voltage cell based on the preset diagnosis condition based on determining that the minimum discharging voltage cell number is the same as the maximum charging voltage cell number.

6. The battery cell swelling and degradation diagnosing apparatus of claim 5, wherein the processor is configured to:
calculate a first voltage slope of the minimum discharging voltage cell and a second voltage slope of a maximum discharging voltage cell from the battery cell-specific voltage values corresponding to the discharging;
diagnose a degradation level of the minimum discharging voltage cell based on a deviation between a first voltage of the minimum discharging voltage cell and a second voltage of the maximum discharging voltage cell based on determining that a difference between the first voltage slope and the second voltage slope is greater than or equal to a preset value;
diagnose the minimum discharging voltage cell as a swelling cell based on determining that the minimum discharging voltage cell satisfies a preset first diagnosis condition; and
diagnose the minimum discharging voltage cell as a degraded cell based on determining that the minimum discharging voltage cell satisfies a preset second diagnosis condition.

7. The battery cell swelling and degradation diagnosing apparatus of claim 6, wherein the processor is configured to:
diagnose the degradation level of the minimum discharging voltage cell as a first level based on determining that the deviation between the first voltage and the second voltage is within a first setting range;
diagnose the degradation level of the minimum discharging voltage cell as a second level based on determining that the deviation between the first voltage and the second voltage is within a second setting range; and
diagnose the degradation level of the minimum discharging voltage cell as a third level based on determining that the deviation between the first voltage and the second voltage is greater than or equal to a specific setting range.

8. The battery cell swelling and degradation diagnosing apparatus of claim 7, wherein the processor is configured to:
diagnose the degradation level of the minimum discharging voltage cell as a warning level based on determining that the deviation between the first voltage and the second voltage is within a range from about 0.6 V or more and less than about 0.8 V;
diagnose the degradation level of the minimum discharging voltage cell as a degradation-expected level based on determining that the deviation between the first voltage and the second voltage is within a range from about 0.8 V or more and less than about 1.0 V; and
diagnose the degradation level of the minimum discharging voltage cell as a hazardous level based on determining that the deviation between the first voltage and the second voltage is greater than or equal to about 1.0 V.

9. The battery cell swelling and degradation diagnosing apparatus of claim 6, wherein the processor is configured to:
diagnose the minimum discharging voltage cell as the swelling cell based on determining that the preset first diagnosis condition that the minimum discharging voltage cell is an outermost battery cell in the battery is satisfied.

10. The battery cell swelling and degradation diagnosing apparatus of claim 6, wherein the processor is configured to:
diagnose the minimum discharging voltage cell as the degraded cell based on determining that the preset second diagnosis condition that a cell resistance value of the minimum discharging voltage cell is within a specific resistance range is satisfied.

11. A cell swelling and degradation diagnosing method comprising:
determining, by a processor, whether a battery is fully charged;
determining, by the processor based on determining that the battery is fully charged, whether a difference between a first voltage of a maximum charging voltage cell and a second voltage of a minimum charging voltage cell, from battery cell-specific voltage values corresponding to charging, is greater than or equal to a preset specific threshold voltage;
storing, by the processor, a maximum charging voltage cell number based on determining that the difference between the first voltage and the second voltage is greater than or equal to the preset specific threshold voltage;
determining, by the processor, whether the battery is being discharged;
obtaining, by the processor based on determining that the battery is being discharged, a minimum discharging voltage cell number from battery cell-specific voltage values corresponding to discharging;
determining, by the processor, whether the obtained minimum discharging voltage cell number is the same as the maximum charging voltage cell number; and
diagnosing whether swelling or degradation is made at a minimum discharging voltage cell based on a preset diagnosis condition, based on determining that the obtained minimum discharging voltage cell number is the same as the maximum charging voltage cell number.

12. The method of claim 11, wherein determining whether the difference is greater than or equal to the preset specific threshold voltage includes:
determining that the battery is fully charged based on determining that a state of charge (SOC) of the battery is at least approximately 100 percent;
extracting the first voltage of the maximum charging voltage cell and the second voltage of the minimum charging voltage cell based on the battery cell-specific voltage values corresponding to the charging; and
determining whether the difference between the first voltage and the second voltage is greater than or equal to the preset specific threshold voltage.

13. The method of claim 11, wherein storing the maximum charging voltage cell number includes:
obtaining a cell number assigned in advance to the maximum charging voltage cell based on determining that the difference between the first voltage of the maximum charging voltage cell and the second voltage of the minimum charging voltage cell is greater than or equal to the preset specific threshold voltage; and
storing the maximum charging voltage cell number in a memory.

14. The method of claim 11, wherein obtaining the minimum discharging voltage cell number includes:
determining that the battery is being discharged based on determining that a vehicle in which the battery is included starts driving;
obtaining the battery cell-specific voltage values corresponding to the discharging;
searching the obtained battery cell-specific voltage values for a minimum discharging voltage cell with a minimum voltage; and
obtaining the minimum discharging voltage cell number by checking a cell number assigned in advance to the minimum discharging voltage cell, based on the minimum discharging voltage cell being found.

15. The method of claim 11, wherein diagnosing whether the swelling or the degradation is made includes:
determining whether the minimum discharging voltage cell number is the same as the maximum charging voltage cell number stored in a memory based on the minimum discharging voltage cell number being found; and
diagnosing whether the swelling or degradation is made at the minimum discharging voltage cell based on the preset diagnosis condition based on determining that the minimum discharging voltage cell number is the same as the maximum charging voltage cell number.

16. The method of claim 15, wherein diagnosing whether the swelling or the degradation is made further includes:
calculating a first voltage slope of the minimum discharging voltage cell and a second voltage slope of a maximum discharging voltage cell from the battery cell-specific voltage values corresponding to the discharging;
diagnosing a degradation level of the minimum discharging voltage cell based on a deviation between a first voltage of the minimum discharging voltage cell and a second voltage of the maximum discharging voltage cell based on determining that a difference between the first voltage slope and the second voltage slope is greater than or equal to a preset value;
diagnosing the minimum discharging voltage cell as a swelling cell based on determining that the minimum discharging voltage cell satisfies a preset first diagnosis condition; and
diagnosing the minimum discharging voltage cell as a degraded cell based on determining that the minimum discharging voltage cell satisfies a preset second diagnosis condition.

17. The method of claim 16, wherein diagnosing the degradation level includes:
diagnosing the degradation level of the minimum discharging voltage cell as a first level based on determining that the deviation between the first voltage and the second voltage is within a first setting range; and
diagnosing the degradation level of the minimum discharging voltage cell as a second level based on determining that the deviation between the first voltage and the second voltage is within a second setting range; and
diagnosing the degradation level of the minimum discharging voltage cell as a third level based on determining that the deviation between the first voltage and the second voltage is greater than or equal to a specific setting range.

18. The method of claim 17, wherein diagnosing the degradation level further includes:
diagnosing the degradation level of the minimum discharging voltage cell as a warning level based on determining that the deviation between the first voltage and the second voltage is within a range from about 0.6 V or more and less than about 0.8 V;
diagnosing the degradation level of the minimum discharging voltage cell as a degradation-expected level based on determining that the deviation between the first voltage and the second voltage is within a range from about 0.8 V or more and less than about 1.0 V; and
diagnosing the degradation level of the minimum discharging voltage cell as a hazardous level based on determining that the deviation between the first voltage and the second voltage is greater than or equal to about 1.0 V.

19. The method of claim 16, wherein diagnosing the minimum discharging voltage cell as the swelling cell includes:
diagnosing the minimum discharging voltage cell as the swelling cell based on determining that the preset first diagnosis condition that the minimum discharging voltage cell is an outermost battery cell in the battery is satisfied.

20. The method of claim 16, wherein diagnosing the minimum discharging voltage cell as the degradation cell includes:
diagnosing the minimum discharging voltage cell as the degraded cell based on determining that the preset second diagnosis condition that a cell resistance value of the minimum discharging voltage cell is within a specific resistance range is satisfied.
